(19) United States
(12) Patent Application Publication
(10) Pub. No.: US 2007/0001724 A1
(43) Pub. Date: Jan. 4, 2007

(54) DELAY LOCKED LOOP CIRCUIT

(75) Inventor: Kwang Jin Na, Anyang-Si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Shi (KR)

(21) Appl. No.: 11/164,762

(22) Filed: Dec. 5, 2005

(30) Foreign Application Priority Data
Jun. 29, 2005 (KR) 2005-57358

(51) Int. Cl. H03L 7/06

(52) U.S. Cl. 327/158

(57) ABSTRACT

A delay locked loop circuit is disclosed. The circuit comprises a clock receiver for outputting an external clock, an inverted clock, which is an inverted version of the external clock, and a reference clock, a multiplexer for receiving the external clock and the inverted clock and selectively outputting any one of the received clocks, a first delay for delaying an output signal from the multiplexer by a first desired delay period, a clock driver for receiving an output signal from the first delay and generating an internal clock, a second delay for delaying an output signal from the clock driver by a second desired delay period to output a feedback clock, and a phase detector for comparing a phase of the feedback clock from the second delay with that of the reference clock from the clock receiver and outputting a first phase control signal for control of a selection operation of the multiplexer and a second phase control signal for control of a delay operation of the first delay in accordance with a result of the comparison.

### FIELD OF THE INVENTION

This application relies for priority upon Korean Patent Application No.: 2005-57358 filed on Jun. 29, 2005, the contents of which are herein incorporated by reference in their entirety. The present patent relates to a delay locked loop circuit, and more particularly to a delay locked loop circuit for adjusting the phase of an internal clock, which is the output of the delay locked loop circuit, to such a proper value that the phase of DQ data or a DQ strobe can be synchronized with that of an external clock.

### DESCRIPTION OF THE RELATED ART

In general, a clock is used in a system or circuit as a reference signal for timing the operation of the system or circuit. The clock may be used to ensure a faster errorless operation of the system or circuit. Meanwhile, when an external clock is used within the system, a time delay (clock skew) may occur by an internal circuit of the system. A phase locked loop (PLL) or delay locked loop (DLL) is generally used to adjust the phase of an internal clock to a proper value to compensate for such a time delay such that DQ data or a DQ strobe is in phase with the external clock.

The PLL is widely used in general fields, but a DLL is widely used in synchronous semiconductor memories, including a Double Data Rate Synchronous DRAM (DDR SDRAM), owing to its advantage of being less influenced by noise than the PLL.

The operation of a conventional DLL circuit will hereinafter be described with reference to FIG. 1, which shows the configuration of the conventional DLL circuit.

First, a clock receiver 100 receives an external clock CLK and an inverted clock CLKB, which is an inverted version of the external clock CLK. A multiplexer (MUX) 110 receives the external clock CLK and the inverted clock CLKB from the clock receiver 100 and selectively outputs any one of them under the control of a MUX controller 170.

Then, a first delay 120 delays the clock selectively outputted from the MUX 110 by a desired delay period. At this time, the delay period is determined by a clock delay controller 180. A clock driver 130 drives an output signal from the first delay 120 to output an internal clock CLK_INT.

Thereafter, a second delay 150 delays an output signal fbclk_dll from the clock driver 130 by a desired delay period to output a feedback clock fbclk. Here, the delay period of the second delay 150 is a modeled version of a delay time which is taken until an internal operation circuit 140 receives the internal clock CLK_INT, which is the output of the DLL circuit, and generates DQ data or a DQ strobe DQS. The second delay 150 delays the signal fbclk_dll by this delay period and outputs the delayed signal as the feedback clock fbclk. In principle, a reference clock refclk from the clock receiver 100, inputted to a phase detector 160 to be described hereinafter, and the feedback clock fbclk must be phase-aligned for accurate synchronization between the external clock CLK and the DQ strobe.

The phase detector 160 compares the phase of the feedback clock fbclk from the second delay 150 with that of the reference clock refclk from the clock receiver 100 and outputs a phase control signal p_ctr for control of the operation of the MUX controller 170 and clock delay controller 180 in accordance with the comparison result. That is, the phase detector 160 compares the phase of the feedback clock fbclk with that of the reference clock refclk and outputs the phase control signal p_ctr for control of the selection operation of the MUX 110 and the delay operation of the first delay 120 in accordance with the comparison result. This phase control operation will hereinafter be described in detail with reference to FIG. 2.

In the initial operation of the DLL circuit, when a rising edge of the feedback clock fbclk is placed ahead of the rising edge of the reference clock refclk by less than half the period of the reference clock refclk as shown in Case I of FIG. 2, the phase detector 160 outputs the phase control signal p_ctr of a high level. The MUX controller 170 controls the MUX 110 in response to the high-level phase control signal p_ctr such that the MUX 110 outputs the external clock CLK. As a result, the MUX 110 is set to output the external clock CLK continuously, irrespective of future level variations of the phase control signal p_ctr, thereby preventing the output clock from the MUX 110 from becoming unstable due to its frequent variations depending on the level variations of the phase control signal p_ctr.

The clock delay controller 180 sequentially increases the delay period of the first delay 120 in response to the high-level phase control signal p_ctr, so that the phase of the feedback clock fbclk supplied along the feedback path is sequentially shifted to a point X as shown in Case I of FIG. 2. Thereafter, when the phase of the feedback clock fbclk nears the point X, the phase detector 160 compares the phase of the feedback clock fbclk with that of the reference clock refclk and repeatedly outputs the phase control signal p_ctr of the high level, which pushes the phase of the feedback clock fbclk backward, or the phase control signal p_ctr of a low level, which pulls the phase of the feedback clock fbclk forward, according to the comparison result, so that the synchronization between the feedback clock fbclk and the reference clock refclk can be maintained.

On the other hand, in the initial operation of the DLL circuit, when the rising edge of the feedback clock fbclk is placed ahead of the rising edge of the reference clock refclk by half the period of the reference clock refclk or more as shown in A of Case II of FIG. 2, the phase detector 160 outputs the phase control signal p_ctr of the low level. Then, the MUX controller 170 controls the MUX 110 in response to the low-level phase control signal p_ctr such that the MUX 110 outputs the inverted clock CLKB of the external clock CLK. Thus, the MUX 110 is set to output the inverted clock CLKB continuously irrespective of future level variations of the phase control signal p_ctr.

Originally, when the phase control signal p_ctr is low in level, the clock delay controller 180 reduces the delay period of the first delay 120 to pull the phase of the feedback clock fbclk forward. However, in the case where the feedback clock fbclk is changed in phase as in B of Case II while being supplied along the feedback path, the phase detector 160 compares the phase of the phase-changed feedback clock fbclk with that of the reference clock refclk and outputs the phase control signal p_ctr of the high level according to the comparison result. As a result, the clock delay controller 180 increases the delay period of the first delay 120 stepwise in response to the high-level phase control signal p_ctr, so that the phase of the phase-changed feedback clock fbclk supplied along the feedback path is sequentially shifted to the point X as shown in B of Case II of FIG. 2.

However, the above-mentioned conventional DLL circuit is disadvantageous in that an error may occur in clock synchronization when the phase of the feedback clock fbclk suffers a change under the influence of system environments, etc. That is, in the initial operation of the DLL circuit, the MUX 110 is set to selectively output the external clock CLK, because the feedback clock fbclk has the phase as in Case I of FIG. 2. Thereafter, if the feedback clock fbclk is changed in phase as in B of Case II due to the influence of the system environments, etc. while being supplied along the feedback path, the phase detector 160 outputs the phase control signal p_ctr of the low level and the clock delay controller 180 reduces the delay period of the first delay 120 stepwise in response to the low-level phase control signal p_ctr. However, in the initial operation of the DLL circuit, the delay period of the first delay 120 is reduced within a limited range, thereby making it impossible to pull the phase of the feedback clock fbclk forward such that it is aligned with the phase of the reference clock refclk. For this reason, an error may take place in the synchronization between the feedback clock fbclk and the reference clock refclk, resulting in occurrence of an error in synchronization between the external clock CLK and the DQ strobe.

### SUMMARY

Therefore, the invention disclosed in the present patent has been made in view of the above problems, and it addresses a need to provide a delay locked loop circuit in which no clock synchronization error occurs in spite of variation in phase of a feedback clock applied to a phase detector in the initial operation of the delay locked loop circuit.

In accordance with the present patent, the above can be accomplished by the provision of a delay locked loop circuit comprising: a clock receiver for inputting an external clock and outputting an inverted clock and a reference clock, the inverted clock being an inverted version of the external clock; a multiplexer for receiving the external clock and the inverted clock and selectively outputting any one of the received clocks; a first delay for delaying an output signal from the multiplexer by a first desired delay period; a clock driver for receiving an output signal from the first delay and generating an internal clock; a second delay for delaying an output signal from the clock driver by a second desired delay period to output a feedback clock; and a phase detector for comparing a phase of the feedback clock from the second delay with that of the reference clock from the clock receiver and outputting a first phase control signal for control of a selection operation of the multiplexer and a second phase control signal for control of a delay operation of the first delay in accordance with a result of the comparison.

The delay locked loop circuit disclosed herein further includes a multiplexer controller for controlling the operation of the multiplexer in response to the first phase control signal and a clock delay controller for controlling the operation of the first delay in response to the second phase control signal.

The multiplexer controller may control the multiplexer according to a level of the first phase control signal such that the multiplexer selects any one of the external clock and inverted clock in an initial operation of the delay locked loop circuit.

The clock delay controller may increase or reduce the first delay period according to a level of the second phase control signal.

The phase detector disclosed herein a first latch for latching status information of the reference clock synchronously with the feedback clock; a first buffer for buffering an output signal from the first latch; a delay for delaying the feedback clock by a predetermined period to output a delayed feedback clock; a second latch for latching the status information of the reference clock synchronously with the delayed feedback clock; a second buffer for buffering an output signal from the second latch; and a logic unit for performing a logical operation with respect to an output signal from the first buffer and an output signal from the second buffer.

The output signal from the first buffer may be the first phase control signal, and an output signal from the logic unit may be the second phase control signal. The logic unit may perform a logical sum operation. The first latch may latch the status information of the reference clock at a rising edge or falling edge of the feedback clock.

The second latch may latch the status information of the reference clock at a rising edge or falling edge of the delayed feedback clock. Also, the first latch and the second latch may be flip-flops.

The first buffer and the second buffer may be inverting buffers.

The output signal from the clock driver to the second delay may be the internal clock.

The reference clock may be in phase with the external clock.

The delay locked loop circuit disclosed herein further includes a duty corrector for correcting a duty of the output signal from the first delay and supplying the resulting signal to the clock driver.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram showing the configuration of a conventional delay locked loop circuit;

FIG. 2 is a waveform diagram illustrating the operation characteristics of the conventional delay locked loop circuit;

FIG. 3 is a block diagram showing the configuration of a delay locked loop circuit according to the present invention;

FIG. 4 is a circuit diagram of a phase detector in the delay locked loop circuit according to the present invention; and

FIG. 5 is a waveform diagram illustrating the operation characteristics of the delay locked loop circuit according to the present invention.

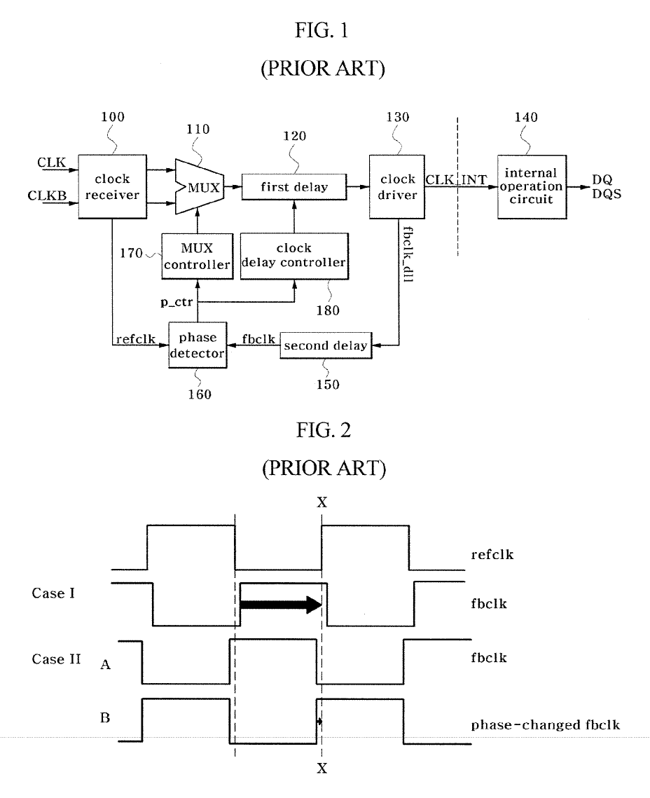

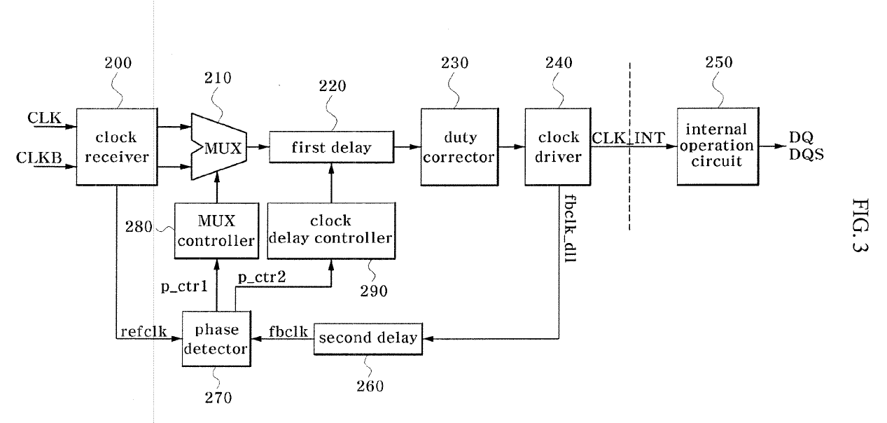

### DESCRIPTION OF VARIOUS EMBODIMENTS

Reference will now be made in detail to the various embodiments of the present patent, examples of which are illustrated in the accompanying drawings, wherein like reference numerals refer to like elements throughout. The embodiments are described below to explain the present patent by referring to the figures.

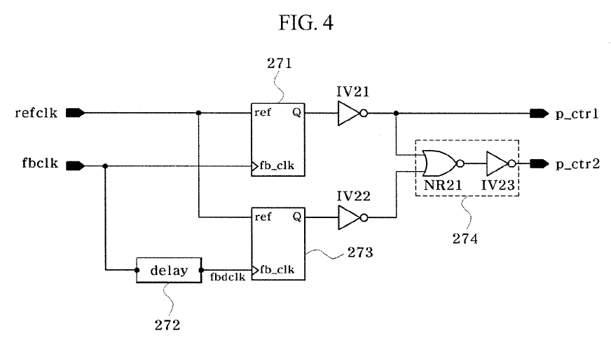

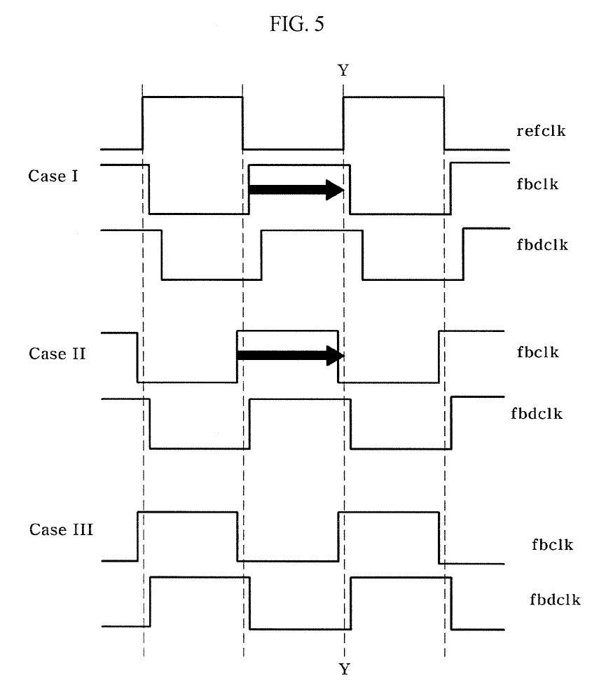

FIG. 3 shows the configuration of an exemplary delay locked loop (DLL) circuit, FIG. 4 shows the configuration of an exemplary phase detector in the DLL circuit, and FIG. 5 illustrates the exemplary operation characteristics of the DLL circuit. The present patent will hereinafter be described with reference to these figures.

As shown in FIG. 3, the exemplary DLL circuit includes a clock receiver 200 for receiving an external clock CLK and outputting an inverted clock CLKB and a reference clock refclk, the inverted clock CLKB being an inverted version of the external clock CLK; a multiplexer (MUX) 210 for receiving the external clock CLK and the inverted clock CLKB from the clock receiver 200 and selectively outputting any one of the received clocks; a first delay 220 for delaying an output signal from the MUX 210 by a first desired delay period; a clock driver 240 for receiving an output signal from the first delay 220 and generating an internal clock CLK_INT; a second delay 260 for delaying an output signal fbclk_dll from the clock driver 240 by a second desired delay period to output a feedback clock fbclk. The exemplary DLL circuit also inlcudes a phase detector 270 for comparing the phase of the feedback clock fbclk from the second delay 260 with that of the reference clock refclk from the clock receiver 200 and outputting a phase control signal p_ctr1 for control of a selection operation of the MUX 210 and a phase control signal p_ctr2 for control of a delay operation of the first delay 220 in accordance with the comparison result; a MUX controller 280 for controlling the operation of the MUX 210 in response to the phase control signal p_ctr1; and a clock delay controller 290 for controlling the operation of the first delay 220 in response to the phase control signal p_ctr2. The exemplary DLL circuit further includes a duty corrector 230 for correcting the duty of the output signal from the first delay 220 and supplying the resulting signal to the clock driver 240.

The operation of the exemplary DLL circuit with the above-stated configuration will hereinafter be described in detail with reference to FIGS. 3 to 5.

As shown in FIG. 3, first, the clock receiver 200 receives the external clock CLK and the inverted clock CLKB of the external clock CLK and supplies the received clocks to the MUX 210. The clock receiver 200 also supplies the reference clock refclk, which is in phase with the external clock CLK. Then, the MUX 210 receives the external clock CLK and the inverted clock CLKB from the clock receiver 200 and selectively outputs any one of them under the control of the MUX controller 280.

Then, the first delay 220 delays the clock selectively outputted from the MUX 210 by the first desired delay period. At this time, the first delay period of the first delay 220 is set to the time required for synchronization between the external clock CLK and DQ data (or a DQ strobe) under the control of the clock delay controller 290.

Thereafter, the duty corrector 230 corrects the duty of the output signal from the first delay 220 and supplies the resulting signal to the clock driver 240, which then drives the supplied signal to output the internal clock CLK_INT. It should be noted here that the duty corrector 230 may be omitted according to a given system.

Next, the second delay 260 delays the output signal fbclk_dll from the clock driver 240 by the second desired delay period to output the feedback clock fbclk. Here, the second delay period of the second delay 260 is a modeled version of a delay time which is taken until an internal operation circuit 250 receives the internal clock CLK_INT, which is the resultant output of the DLL circuit, and generates the DQ data or DQ strobe DQS. The second delay 260 delays the signal fbclk_dll by this delay period and outputs the delayed signal as the feedback clock fbclk. In principle, the reference clock refclk, inputted to the phase detector 270 to be described hereinafter, and the feedback clock fbclk must be phase-aligned for accurate synchronization between the external clock CLK and the DQ strobe.

The phase detector 270 compares the phase of the feedback clock fbclk from the second delay 260 with that of the reference clock refclk from the clock receiver 200 and outputs the phase control signal p_ctr1 for control of the operation of the MUX controller 280 and the phase control signal p_ctr2 for control of the operation of the clock delay controller 290 in accordance with the comparison result. That is, the phase detector 270 compares the phase of the feedback clock fbclk with that of the reference clock refclk and the phase of a delayed feedback clock fbdclk, which is a delayed version of the feedback clock fbclk, with that of the reference clock refclk, respectively, and outputs the phase control signal p_ctr1 for control of the selection operation of the MUX 210 and the phase control signal p_ctr2 for control of the delay operation of the first delay 220 in accordance with the comparison results, respectively. This operation of the phase detector 270 will hereinafter be described in detail with reference to FIG. 4.

As shown in FIG. 4, the phase detector 270 includes a flip-flop 271 for latching status information of the reference clock refclk synchronously with the feedback clock fbclk, an inverter IV21 for inverting/buffering an output signal from the flip-flop 271 and outputting the resulting signal as the phase control signal p_ctr1, a delay 272 for delaying the feedback clock fbclk by a predetermined period to output the delayed feedback clock fbdclk, a flip-flop 273 for latching the status information of the reference clock refclk synchronously with the delayed feedback clock fbdclk, an inverter IV22 for inverting/buffering an output signal from the flip-flop 273, and a logic unit 274 for performing a logical sum operation with respect to the output signal from the inverter IV21 and an output signal from the inverter IV22 and outputting the resulting signal as the phase control signal p_ctr2.

The phase detector 270 is operated in the following manner. First, the flip-flop 271 receives the reference clock refclk and the feedback clock fbclk and latches and outputs the status information of the reference clock refclk at a rising edge of the feedback clock fbclk. As a result, the flip-flop 271 outputs a high-level signal when the reference clock refclk assumes a high level at the rising edge of the feedback clock fbclk, and a low-level signal when the reference clock refclk assumes a low level at the rising edge of the feedback clock fbclk. Then, the inverter IV21 inverts the output signal from the flip-flop 271 and outputs the inverted signal as the phase control signal p_ctr1.

Meanwhile, the flip-flop 273 receives the reference clock refclk and the delayed feedback clock fbdclk and latches and outputs the status information of the reference clock refclk at a rising edge of the delayed feedback clock fbdclk. Thus, the flip-flop 273 outputs a high-level signal when the reference clock refclk assumes a high level at the rising edge of the delayed feedback clock fbdclk, and a low-level signal when the reference clock refclk assumes a low level at the rising edge of the delayed feedback clock fbdclk. Then, the inverter IV22 inverts and outputs the output signal from the flip-flop 273. The logic unit 274, which is composed of a NOR gate NR21 and an inverter IV23, performs the logical sum operation with respect to the output signal from the inverter IV21 and the output signal from the inverter IV22 and outputs the resulting signal as the phase control signal p_ctr2. Here, the delayed feedback clock fbdclk is generated by delaying the feedback clock fbclk by the predetermined period through the delay 272. Namely, it is generated by, in consideration of an error in phase variation of the feedback clock fbclk resulting from system environment variations, delaying the feedback clock fbclk by a period longer than a period of such an error.

A description will hereinafter be given of a phase control operation of the present DLL circuit based on the above-stated operation of the phase detector 270 with reference to FIG. 5.

First, in the initial operation of the DLL circuit, when a rising edge of the feedback clock fbclk is placed ahead of a rising edge of the reference clock refclk by less than half the period of the reference clock refclk as shown in Case I of FIG. 5, the phase detector 270 outputs the phase control signal p_ctr1 of a high level and the phase control signal p_ctr2 of a high level. That is, in Case I of FIG. 5, because the reference clock refclk assumes a low level at the rising edge of the feedback clock fbclk where the feedback clock fbclk rises from low to high in level, the flip-flop 271 outputs a low-level signal, and the inverter IV21 inverts this low-level signal and outputs the inverted signal as the phase control signal p_ctr1 of the high level. Since the reference clock refclk is also low in level at the rising edge of the delayed feedback clock fbdclk, the flip-flop 273 outputs a low-level signal, and the inverter IV22 inverts this low-level signal and outputs the resulting high-level signal. As a result, the phase control signal p_ctr2 from the logic unit 274 becomes high in level.

The MUX controller 280 controls the MUX 210 in response to the high-level phase control signal p_ctr1 such that the MUX 210 outputs the external clock CLK. As a result, the MUX 210 is set to output the external clock CLK continuously irrespective of future level variations of the phase control signal p_ctr1, thereby preventing the output clock from the MUX 210 from becoming unstable due to its frequent variations depending on the level variations of the phase control signal p_ctr1. The clock delay controller 290 sequentially increases the first delay period of the first delay 220 in response to the high-level phase control signal p_ctr2, so that the phase of the feedback clock fbclk supplied along the feedback path is sequentially shifted to a point Y as shown in Case I of FIG. 5. Thereafter, when the phase of the feedback clock fbclk nears the point Y, the phase detector 270 compares the phase of the feedback clock fbclk with that of the reference clock refclk and repeatedly outputs the phase control signal p_ctr2 of the high level, which pushes the phase of the feedback clock fbclk backward, or the phase control signal p_ctr2 of a low level, which pulls the phase of the feedback clock fbclk forward, according to the comparison result, so that the synchronization between the feedback clock fbclk and the reference clock refclk can be maintained.

Meanwhile, in the DLL circuit according to the present invention, no error occurs in clock synchronization even when the phase of the feedback clock fbclk suffers a change under the influence of the system environments, etc. That is, in the initial operation of the DLL circuit, the MUX 210 is set to selectively output the external clock CLK, because the feedback clock fbclk has the phase as in Case I of FIG. 5. Thereafter, in the case where the feedback clock fbclk is changed in phase as in Case II due to the influence of system environments, etc. while being supplied along the feedback path, a clock synchronization error does not occur according to the present invention, although it occurs conventionally.

In detail, if the feedback clock fbclk is changed in phase as in Case II due to the influence of the system environments, etc. while being supplied along the feedback path, the output signal from the flip-flop 271 becomes high in level, thereby causing the phase control signal p_ctr1 from the inverter IV21 to go to a low level. However, even in this case, the phase of the delayed feedback clock fbdclk from the delay 272 is placed behind that of the feedback clock fbclk by the delay period of the delay 272, so the rising edge of the feedback clock fbclk is placed ahead of the rising edge of the reference clock refclk by less than half a period of the reference clock refclk as shown in Case II of FIG. 5. At this time, because the reference clock refclk is low in level at the rising edge of the delayed feedback clock fbdclk, the flip-flop 273 outputs a low-level signal, and the inverter IV22 inverts this low-level signal and outputs the resulting high-level signal. As a result, the logic unit 272 outputs the high-level phase control signal p_ctr2 depending on the high-level signal from the inverter IV22 irrespective of the output signal from the inverter IV21.

Then, the clock delay controller 290 increases the first delay period of the first delay 220 stepwise in response to the high-level phase control signal p_ctr2, so that the phase of the feedback clock fbclk supplied along the feedback path is sequentially shifted to the point Y as shown in Case II of FIG. 5. Thereafter, when the phase of the feedback clock fbclk nears the point Y, the phase detector 270 compares the phase of the feedback clock fbclk with that of the reference clock refclk and repeatedly outputs the phase control signal p_ctr2 of the high level, which pushes the phase of the feedback clock fbclk backward, or the phase control signal p_ctr2 of the low level, which pulls the phase of the feedback clock fbclk forward, according to the comparison result, so that the synchronization between the feedback clock fbclk and the reference clock refclk can be maintained. In this manner, according to the present invention, even though the feedback clock fbclk is changed in phase from Case I to Case II due to the influence of the system environments, etc. while being supplied along the feedback path, it is possible to establish synchronization between the feedback clock fbclk and the reference clock refclk and, furthermore, the synchronization between the external clock CLK and the DQ data (or DQ strobe).

On the other hand, the logic unit 274, which performs the logical sum operation, is provided in the present invention to prevent occurrence of an error in Case III of FIG. 5. That is, in the case where the rising edge of the feedback clock fbclk is placed ahead of the rising edge of the reference clock refclk and the rising edge of the delayed feedback clock fbdclk is placed behind the rising edge of the reference clock refclk, as shown in Case III of FIG. 5, a clock synchronization error may occur by pulling the phase of the feedback clock fbclk forward, in spite of the fact that synchronization can be established by pushing the phase of the feedback clock fbclk backward. In this connection, in the present invention, the logic unit 274 performs the logical sum operation with respect to the high-level signal from the inverter IV21 along with the low-level signal from the inverter IV22 to output the phase control signal p_ctr2 of the high level, thereby allowing the clock delay controller 290 to increase the delay period of the first delay 220 so that the feedback clock fbclk can be synchronized with the reference clock refclk.

Although the flip-flop 271 and the flip-flop 273 have been disclosed as being operated synchronously with the rising edges of the feedback clock fbclk and delayed feedback clock fbdclk, respectively, they may be operated synchronously with falling edges of those clocks according to a given embodiment.

As apparent from the above description, a delay locked loop circuit according to the present patent is able to control selection of an external clock and an inverted external clock and setting of the clock delay period, independently, using two phase control signals from a phase detector. Therefore, in the initial operation of the delay locked loop circuit, no clock synchronization error occurs even though the phase of a feedback clock applied to the phase detector suffers a change.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed as new and desired to be protected by Letters Patent of the United States is:

1. A delay locked loop circuit comprising:
a clock receiver for inputting an external clock and outputting an inverted clock and a reference clock, the inverted clock being an inverted version of the external clock;
a multiplexer for receiving the external clock and the inverted clock and selectively outputting any one of the received clocks;
a first delay for delaying an output signal from the multiplexer by a first desired delay period;
a clock driver for receiving an output signal from the first delay and generating an internal clock;
a second delay for delaying an output signal from the clock driver by a second desired delay period to output a feedback clock; and
a phase detector for comparing a phase of the feedback clock from the second delay with that of the reference clock from the clock receiver and outputting a first phase control signal for control of a selection operation of the multiplexer and a second phase control signal for control of a delay operation of the first delay in accordance with a result of the comparison.

2. The delay locked loop circuit as set forth in claim 1, further comprising:
a multiplexer controller for controlling the operation of the multiplexer in response to the first phase control signal; and
a clock delay controller for controlling the operation of the first delay in response to the second phase control signal.

3. The delay locked loop circuit as set forth in claim 2, wherein the multiplexer controller controls the multiplexer according to a level of the first phase control signal such that the multiplexer selects any one of the external clock and inverted clock in an initial operation of the delay locked loop circuit.

4. The delay locked loop circuit as set forth in claim 2, wherein the clock delay controller increases or reduces the first delay period according to a level of the second phase control signal.

5. The delay locked loop circuit as set forth claim 1, wherein the phase detector includes:
a first latch for latching status information of the reference clock synchronously with the feedback clock;
a first buffer for buffering an output signal from the first latch;
a delay for delaying the feedback clock by a predetermined period to output a delayed feedback clock;
a second latch for latching the status information of the reference clock synchronously with the delayed feedback clock;
a second buffer for buffering an output signal from the second latch; and
a logic unit for performing a logical operation with respect to an output signal from the first buffer and an output signal from the second buffer.

6. The delay locked loop circuit as set forth in claim 5, wherein the output signal from the first buffer is the first phase control signal, and an output signal from the logic unit is the second phase control signal.

7. The delay locked loop circuit as set forth in claim 5, wherein the logic unit performs a logical sum operation.

8. The delay locked loop circuit as set forth in claim 5, wherein the first latch latches the status information of the reference clock at a rising edge or falling edge of the feedback clock.

9. The delay locked loop circuit as set forth in claim 5, wherein the second latch latches the status information of the reference clock at a rising edge or falling edge of the delayed feedback clock.

10. The delay locked loop circuit as set forth in claim 8, wherein the first latch and the second latch are flip-flops.

11. The delay locked loop circuit as set forth in claim 5, wherein the first buffer and the second buffer are inverting buffers.

12. The delay locked loop circuit as set forth in claim 1, wherein the output signal from the clock driver to the second delay is the internal clock.

13. The delay locked loop circuit as set forth in claim 1, wherein the reference clock is in phase with the external clock.

14. The delay locked loop circuit as set forth in claim 1, further comprising a duty corrector for correcting the duty of the output signal from the first delay and supplying the resulting signal to the clock driver.

15. A delay locked loop circuit comprising:
a first phase control signal for controlling selection of any one of an external clock and an inverted clock from an external clock receiver, the inverted clock being an inverted version of the external clock;
a second phase control signal for controlling setting of a delay period of a selected one of the external clock and inverted clock; and
a phase detector for receiving a reference clock and a feedback clock of a delay locked loop and generating the first and second phase control signals based on the reference clock and feedback clock, wherein the first phase control signal and the second phase control signal are generated along different paths in the phase detector.

16. The delay locked loop circuit as set forth in claim 15, further comprising:
a multiplexer for receiving the external clock and the inverted clock and selectively outputting any one of the received clocks;
a delay for delaying an output signal from the multiplexer by a desired delay period;
a multiplexer controller for controlling an operation of the multiplexer in response to the first phase control signal; and
a clock delay controller for controlling an operation of the delay in response to the second phase control signal.

17. The delay locked loop circuit as set forth in claim 16, wherein the multiplexer controller controls the multiplexer according to a level of the first phase control signal such that the multiplexer selects any one of the external clock and inverted clock in an initial operation of the delay locked loop circuit.

18. The delay locked loop circuit as set forth in claim 16, wherein the clock delay controller increases or reduces the delay period according to a level of the second phase control signal.

19. The delay locked loop circuit as set forth in claim 15, wherein the phase detector includes:
a first latch for latching status information of the reference clock synchronously with the feedback clock;
a first buffer for buffering an output signal from the first latch;
a delay for delaying the feedback clock by a predetermined period to output a delayed feedback clock;
a second latch for latching the status information of the reference clock synchronously with the delayed feedback clock;
a second buffer for buffering an output signal from the second latch; and
a logic unit for performing a logical operation with respect to an output signal from the first buffer and an output signal from the second buffer.

20. The delay locked loop circuit as set forth in claim 19, wherein the output signal from the first buffer is the first phase control signal, and an output signal from the logic unit is the second phase control signal.

21. The delay locked loop circuit as set forth in claim 19, wherein the logic unit performs a logical sum operation.

22. The delay locked loop circuit as set forth in claim 19, wherein the first latch latches the status information of the reference clock at a rising edge or falling edge of the feedback clock.

23. The delay locked loop circuit as set forth in claim 19, wherein the second latch latches the status information of the reference clock at a rising edge or falling edge of the delayed feedback clock.

24. The delay locked loop circuit as set forth in claim 22, wherein the first latch and the second latch are flip-flops.

25. The delay locked loop circuit as set forth in claim 19, wherein the first buffer and the second buffer are inverting buffers.

26. The delay locked loop circuit as set forth in claim 19, wherein the reference clock is in phase with the external clock.
